(19) United States
(12) Patent Application Publication
(10) Pub. No.: US 2009/0051037 A1
(43) Pub. Date: Feb. 26, 2009

(54) SEMICONDUCTOR DEVICE AND METHOD OF MANUFACTURE THEREOF

(76) Inventor: Masahiro JOEI, Toyama (JP)

Correspondence Address: MCDERMOTT WILL & EMERY LLP, 600 13TH STREET, NW, WASHINGTON, DC, 20005-3096, US

(21) Appl. No.: 12/192,328

(22) Filed: Aug. 15, 2008

(30) Foreign Application Priority Data
Aug. 24, 2007 (JP) 2007-218119

(51) Int. Cl. H01L 23/48; H01L 21/44

(52) U.S. Cl. 257/768; 438/682; 257/E23.01; 257/E21.476

(57) ABSTRACT

A semiconductor device relating to the present invention has multiple gate electrodes arranged on a semiconductor substrate at a narrow spacing and an interlayer insulating film covering the gate electrodes. The interlayer insulating film consists of a hygroscopic insulating film filling gate electrode spacing with a thinner thickness on the gate electrodes than the film thickness on the flat surface of the semiconductor substrate and low-hygroscopic insulating film formed on the hygroscopic insulating film. This structure enables suppressing an increase of contact resistance due to H₂O liberated from the hygroscopic insulating film even if very fine contact is formed between the adjacent gate electrodes.

### CROSS-REFERENCE TO RELATED APPLICATION

The present application claims the benefit of Japanese Patent Application No. 2007-218119 filed Aug. 24, 2007, the subject matter of which is incorporated herein by reference.

### BACKGROUND OF THE INVENTION

1. Field of the Invention

The present invention relates to a semiconductor device having an interlayer insulating film and a method of manufacture thereof.

2. Description of the Related Art

In a semiconductor integrated circuit device (hereafter referred to as a semiconductor device), design rules have been continuously reduced for improving the degree of integration and electric characteristics. In recent semiconductor devices, a multilayer wiring structure is adopted and an interlayer insulating film is arranged between the respective wiring layers. FIG. 5 is a sectional view showing the structure of a prior semiconductor device having such an interlayer insulating film.

In the semiconductor device shown in FIG. 5, multiple gate electrodes 52 are arranged on a semiconductor substrate 50. Each gate electrode 52 is formed on the semiconductor substrate 50 via a thin gate insulating film 51. Side walls 53 consisting of an insulating film are formed on both sides of each gate electrode 52. In a recent semiconductor device having fine patterns, the gate electrodes 52 are closely arranged in many cases. In a part of region on the semiconductor substrate 50, a gate electrode spacing 54 (here, the minimum spacing between side walls 53) is narrowed to about several tens nm though it is also dependent upon the layout of circuit patterns.

On the gate electrodes 52, an interlayer insulating film 60 for electrically insulating the gate electrodes 52 and wires formed in a layer upper than the gate electrodes 52 is formed. In a recent semiconductor device with a narrow gate electrode spacing 54, a laminated film obtained by depositing a hygroscopic insulating film 55 and a low-hygroscopic insulating film 56 in order from the lower layer is used as an interlayer insulating film 60 (e.g., reference Japanese Laid-Open Patent Publication 08-51108, etc.) to fill the gate electrode spacing 54 without generating defects such as voids, etc. The low-hygroscopic insulating film 56 of the upper layer is planarized to form wires on the upside thereof. For example, an O₃-TEOS film formed by a low-temperature CVD (Chemical Vapor Deposition) method with O₃ (ozone) and TEOS (Tetraethyl Orthosilicate) as starting materials is used for the hygroscopic insulating film 55. A plasma TEOS film formed by a plasma CVD method with TEOS as starting materials is used for the low-hygroscopic insulating film 56.

In FIG. 5, a contact for electrically connecting wires formed in a layer upper than the interlayer insulating film 60 and impurity regions (e.g., a source region and a drain region) which are a part of semiconductor elements including the gate electrodes 52 and formed on the surface of semiconductor substrate 50. The contact is constructed by a contact hole 57 passing through the interlayer insulating film 60 and a contact plug 58 filled inside the contact hole 57.

The semiconductor device shown in FIG. 5 is formed by a step for forming the gate electrodes 52 and the side walls 53 on the semiconductor substrate 50, a step for forming the hygroscopic insulating film 55, a step for forming the low-hygroscopic insulating film 56 on the hygroscopic insulating film 55, a step for planarizing the low-hygroscopic insulating film 56, and a step for forming the contact.

On the other hand, FIG. 6 is a chart showing gap-fill properties of the O₃-TEOS film being the hygroscopic insulating film 55 and the plasma TEOS film being the low-hygroscopic insulating film 56. Here, the gap-fill property means the minimum spacing of wiring patterns, such as gate electrodes, filled with the insulating film without generating any void when the film is deposited. FIG. 6 shows data in case the height of gate electrodes 52 of FIG. 5 is 100 nm. From FIG. 6, it can be understood that the O₃-TEOS film has superior gap-fill property to the plasma TEOS film and has satisfactory ability to fill the spacing even if the gate electrode spacing 54 is 20 nm or less. Therefore, the O₃-TEOS film has been widely used as an insulating film for filling narrow wiring spacing in recent very fine semiconductor devices.

### SUMMARY OF THE INVENTION

In the semiconductor device having fine patterns as described above, the contact resistance of the contact plug 58 and the resistance of an impurity region become big factors of lowering operating speed, etc. Therefore, a low-resistance refractory metal silicide layer, such as a nickel silicide (NiSi) layer, is formed on the surface of a silicon single crystal substrate formed with impurity regions. FIG. 7 is a graph showing a relationship between the dimension of the contact and the contact resistance. Here, the contact resistance comprises a contact resistance between the contact plug 58 and the nickel silicide layer. In FIG. 7, the horizontal axis corresponds to the contact diameter (the inner diameter of the contact hole 57), and the vertical axis corresponds to the contact resistance. The total film thickness 59a of the interlayer insulating film 60 is 250 nm, and the maximum film thickness 59 of the hygroscopic insulating film 55 (the thickness from the surface of the semiconductor substrate 50 to the upside of the hygroscopic insulating film 55 deposited on the gate electrodes 52) is 200 nm (see FIG. 5). Namely, the low-hygroscopic insulating film 56 having thickness of 50 nm is deposited on the hygroscopic insulating film 55 formed on the gate electrodes 52. As shown in FIG. 7, the contact resistance increases with decreasing the contact diameter. Particularly, when the contact diameter is microfined to 80 nm or less, a rise of the contact resistance becomes striking.

FIG. 8 is a graph showing a relationship between the above contact resistance and the ratio of film thickness of the hygroscopic insulating film 55 occupying in the total film thickness 59a of the interlayer insulating film 60. In FIG. 8, the horizontal axis corresponds to the ratio of film thickness, and the vertical axis corresponds to the contact resistance. The total film thickness 59a of the interlayer insulating film 60 is 250 nm, and the contact diameter is 80 nm. As shown in FIG. 8, when the ratio of film thickness of the hygroscopic insulating film 55 occupying in the total film thickness 59a increases, the contact resistance increases. By an analysis of the present inventor, this phenomenon occurs due to the fact that moisture (H₂O) liberated from the hygroscopic insulating film 55 exposed as the inner surface of the contact hole 57 and the nickel silicide layer on the semiconductor substrate 50 are reacted during dry etching for forming the contact hole 57 and thus the surface of semiconductor substrate 50 is oxidized. From FIG. 8, it can be understood that the ratio of the hygroscopic insulating film 55 occupying in the total film thickness 59a of the interlayer insulating film 60 must be 70% or less to suppress an increase of the contact resistance.

The film thickness of the hygroscopic insulating film 55 deposited on the semiconductor substrate 50 was made to be about the same as the height of the gate electrodes 52 to fill the gate electrode spacing 54 without generating defects such as voids, etc. before. When the hygroscopic insulating film 55 is deposited in a state of satisfying this condition, the hygroscopic insulating film 55 having a film thickness same as the height of the gate electrodes 52 is deposited on the gate electrodes 52. Namely, the maximum film thickness 59 is double the film thickness of the hygroscopic insulating film 55 deposited in a flat region of the semiconductor substrate 50. In this case, for example, when the total film thickness 59a of the interlayer insulating film 60 is 250 nm and the height of the gate electrodes 52 is 100 nm, the ratio of the hygroscopic insulating film 55 occupying in the total film thickness 59a of interlayer insulating film 60 becomes 200/250×100=80%. Accordingly, the ratio of the hygroscopic insulating film 55 occupying in the total film thickness 59a of the interlayer insulating film 60 in the gate electrode spacing 54 is more than 70%. Therefore, there was the problem that moisture was liberated from the side wall of the contact hole 57 in dry etching for forming the contact hole 57 shown in FIG. 5 (mainly the contact hole 57 formed in the narrow gate electrode spacing 54), as a result, the contact resistance increased. Such an increase of the contact resistance is realized when the gate electrode spacing 54 is as narrow as about several tens nm. When the gate electrode spacing 54 is narrowed with the miniaturization of a future semiconductor device, the operating speed of semiconductor device is greatly reduced.

The present invention is proposed in view of the above prior circumstance and has the objective of providing a semiconductor device capable of suppressing the increase of the contact resistance even if a very fine contact of 80 nm or less in diameter is formed.

To resolve the above problem, the following technical means are adopted in the present invention. First, the present invention is premised upon a semiconductor device having multiple convexes formed on a semiconductor substrate, an interlayer insulating film covering the multiple convexes, a through-hole passing through the interlayer insulating film between the adjacent convexes and conductor plug filling the through-hole. Then, in the semiconductor device relating to the present invention, the interlayer insulating film is provided with a hygroscopic insulating film filling between the convexes adjacent to each other and having a thinner film thickness on the convexes than a film thickness on the flat surface of the semiconductor substrate and a low-hygroscopic insulating film formed on the hygroscopic insulating film. Here, the hygroscopic insulating film refers to an insulating film containing relatively large moisture such as an O₃-TEOS film and the like. The low-hygroscopic insulating film refers to an insulating film including relatively less moisture such as a plasma TEOS film and the like.

In this structure, the film thickness of the hygroscopic insulating film taken as a reason for the increase of the contact resistance becomes necessary minimum. Therefore, the increase of contact resistance can be suppressed even if very small contacts are formed in the interlayer insulating film including the hygroscopic insulating film. As a result, the contact resistance can be stabilized and semiconductor devices can be stably formed at a high production yield.

In the above structure, for example, the multiple convexes are gate electrodes formed on the semiconductor substrate. A refractory metal silicide layer may also be formed on the surface of the semiconductor substrate between the convexes adjacent to each other. Moreover, the film thickness of the hygroscopic insulating film on the convexes is preferably 5 nm or more. This structure is more suitable for a semiconductor device where a diameter of the through-hole is 80 nm or less.

On the other hand, the present invention can also provide a method for manufacturing a semiconductor device in another view point. Namely, in the method for manufacturing a semiconductor device relating to the present invention, first, gate electrodes are formed on a semiconductor substrate. Next, a hygroscopic insulating film covering the gate electrodes is formed. A first low-hygroscopic insulating film is formed on the hygroscopic insulating film. Successively, the surface of the laminated film consisting of the hygroscopic insulating film and the first low-hygroscopic insulating film is planarized. At this time, the hygroscopic insulating film on the gate electrodes exposes to the upper surface, and the film thickness of the hygroscopic insulating film is reduced. A second low-hygroscopic insulating film is formed on the planarized laminated film. Then, a through-hole passing through the second low-hygroscopic insulating film and the hygroscopic insulating film with the reduced film thickness is formed, and a conductor is filled into the through-hole.

For example, an O₃-TEOS film can be used for the hygroscopic insulating film. A plasma TEOS film can be used in the first low-hygroscopic insulating film. Also, a plasma TEOS film can be used in the second low-hygroscopic insulating film. For example, the above planarizing can be carried out by chemical mechanical polishing or etch back using dry etching, etc.

The present invention enables making the film thickness of the hygroscopic insulating film as the reason for increasing contact resistance to the necessary minimum. Therefore, the increase of contact resistance can be suppressed even if very fine contacts are formed in the interlayer insulating film including the hygroscopic insulating film. As a result, it enables stably manufacturing a semiconductor device at a high production yield.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a semiconductor device in an embodiment relating to the present invention.

FIG. 2 is a chart showing the maximum film thickness and the film thickness ratio of the hygroscopic insulating film in an embodiment relating to the present invention.

FIG. 3 is a graph showing a relationship between the contact diameter and the contact resistance in an embodiment relating to the present invention.

FIGS. 4A to 4F are sectional views showing a manufacturing process for a semiconductor device in an embodiment relating to the present invention.

FIG. 5 is a sectional view showing a prior semiconductor device.

FIG. 6 is a chart showing gap-fill properties of prior hygroscopic insulating film and low-hygroscopic insulating film.

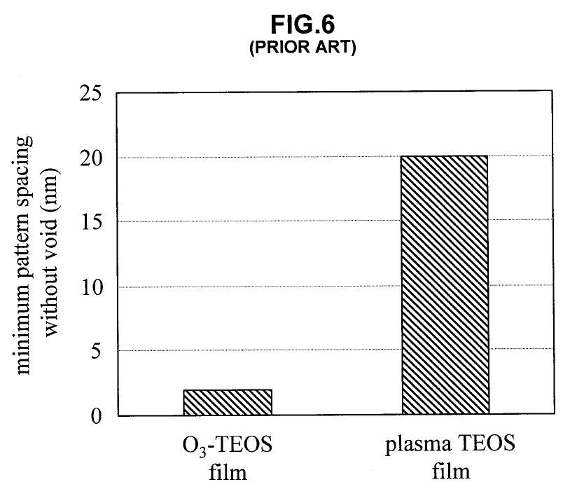

FIG. 7 is a graph showing a prior relationship between the contact diameter and the contact resistance.

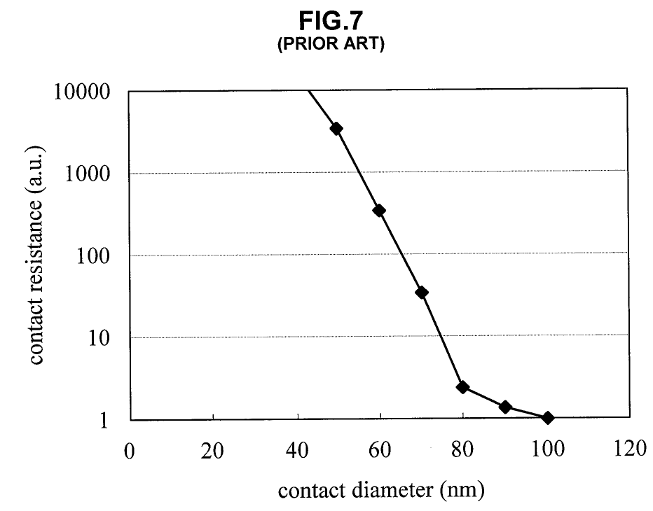

FIG. 8 is a graph showing a prior relationship between the film thickness ratio and the contact resistance of a hygroscopic insulating film.

### DETAILED DESCRIPTION OF THE PREFERRED EMBODIMENTS

An embodiment relating to the present invention is described hereafter with reference to the attached drawings. In the following embodiment, the present invention is embodied as a semiconductor device having an interlayer insulating film consisting of a laminated film comprising a hygroscopic insulating film made of an O₃-TEOS film and low-hygroscopic insulating film made of a plasma TEOS film.

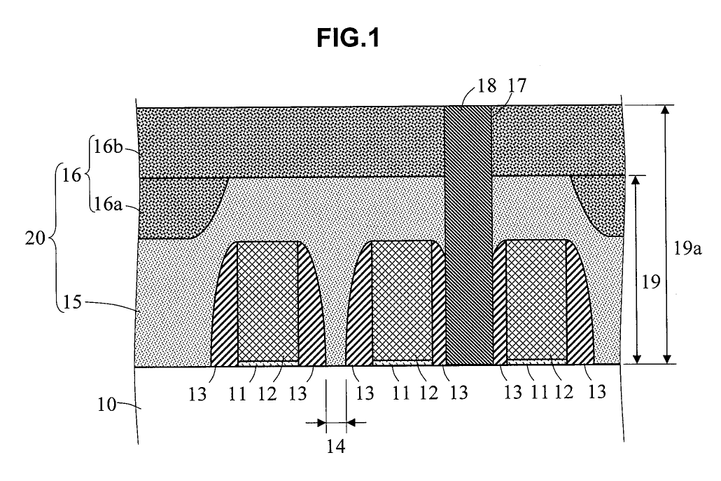

FIG. 1 is a sectional view showing a structure of principal parts of a semiconductor device in an embodiment relating to the present invention. As shown in FIG. 1, the semiconductor device of this embodiment has multiple (three in FIG. 1) gate electrodes 12 provided on a semiconductor substrate 10 consisting of a silicon single crystal substrate via a thin gate insulating film 11. Side walls 13 consisting of an insulating film, such as a silicon nitride film or a silicon oxide film, etc. are provided on the lateral surfaces of each gate electrode 12. Here, a gate electrode spacing 14 becomes about several tens nm. The gate electrode spacing 14 is the minimum spacing between the side walls 13 provided for the gate electrodes 12 adjacent to each other.

The gate electrodes 12 are covered by an interlayer insulating film 20. In this embodiment, the interlayer insulating film 20 is constructed by a laminated film consisting of a hygroscopic insulating film 15 made of an O₃-TEOS film and a low-hygroscopic insulating film 16 made of a plasma TEOS film. The hygroscopic insulating film 15 is provided just above the gate electrodes 12. In the semiconductor device of this embodiment, the hygroscopic insulating film 15 is provided in a state that the film thickness on the gate electrodes 12 becomes thinner than the film thickness of a flat surface of the semiconductor substrate 10. Here, the flat surface means a region capable of flat depositing a film, such as an insulating film, etc., without being affected by ambient irregularities. For example, in FIG. 1, the flat surface is a region where the hygroscopic insulating film 15 is deposited at a height of same extent as the gate electrodes 12 on the semiconductor substrate 10 other than the gate electrode spacing 14. Then, the low-hygroscopic insulating film 16 is provided on the hygroscopic insulating film 15. The surface of the low-hygroscopic insulating film 16 is planarized over the entire surface of semiconductor substrate 10, and wires of upper layer and an interlayer insulating film of upper layer, etc. are formed on the upside thereof.

Contacts for electrically connecting wires provided on a layer upper than the interlayer insulating film 20 and the semiconductor substrate 10 are formed in the interlayer insulating film 20. The contacts are constituted by a contact hole 17 passing through the interlayer insulating film 20 and a conductive contact plug 18 filling the contact hole 17. FIG. 1 illustrates only one contact for electrically connecting to the semiconductor substrate 10 between the center gate electrode 12 and the right gate electrode 12 in three gate electrodes in the figure.

Impurity regions (non-illustrated) which are parts of semiconductor elements including the gate electrodes 12 are formed in surface portion of the semiconductor substrate. For example, when the semiconductor element is a field-effect transistor, the impurity regions are a source region and a drain region. A nickel silicide layer being a refractory metal silicide is provided on the surface of the impurity region.

As is well-known, such a nickel silicide layer is formed by depositing a refractory metal (it is nickel here) over the entire surface of the semiconductor substrate 10 in a state that the gate electrodes 12 and the side walls 13 are formed on the semiconductor substrate 10 and then carrying out heat treatment. In a semiconductor device arranged with the gate electrodes 12 at the narrow gate electrode spacing 14 of about several tens nm, the resistance of gate electrodes 12 must be reduced to suppress a reduction of operating speed of the semiconductor device. Therefore, when the gate electrode 12 is constructed with a material based on silicon such as an N-type or P-type polycrystalline silicon, the nickel silicide layer is also formed in the surface portion of the gate electrode 12.

Thus, when the nickel silicide layer is also formed in the surface portion of the gate electrode 12, if the nickel silicide layer exposes, it becomes a reason for process contamination, etc. in manufacturing steps of the semiconductor device after the nickel silicide layer is formed. Therefore, the hygroscopic insulating film 15 on the each gate electrode 12 must have a minimum film thickness that the nickel silicide layer on the gate electrode 12 does not expose. It is enough if the film thickness is 5 nm. Therefore, the minimum film thickness of the hygroscopic insulating film 15 covering the surface of the each gate electrode 12 is made to 5 nm in this embodiment.

In this structure, for example, when the height of gate electrodes 12 is 100 nm, the maximum film thickness 19 which is a thickness from the surface of the semiconductor substrate 10 to the highest position of the hygroscopic insulating film 15 (the upside of the hygroscopic insulating film 15 above the gate electrodes 12) becomes 105 nm. Namely, the film thickness of the hygroscopic insulating film 15 in the gate electrode spacing 14 becomes 105 nm.

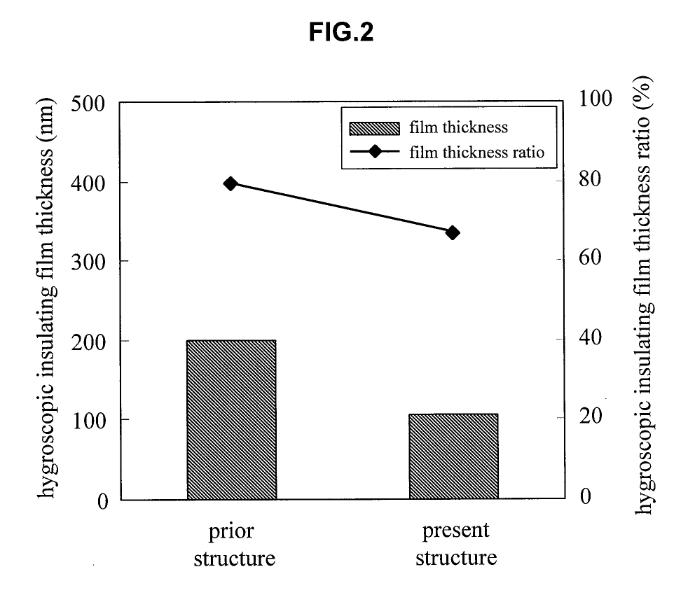

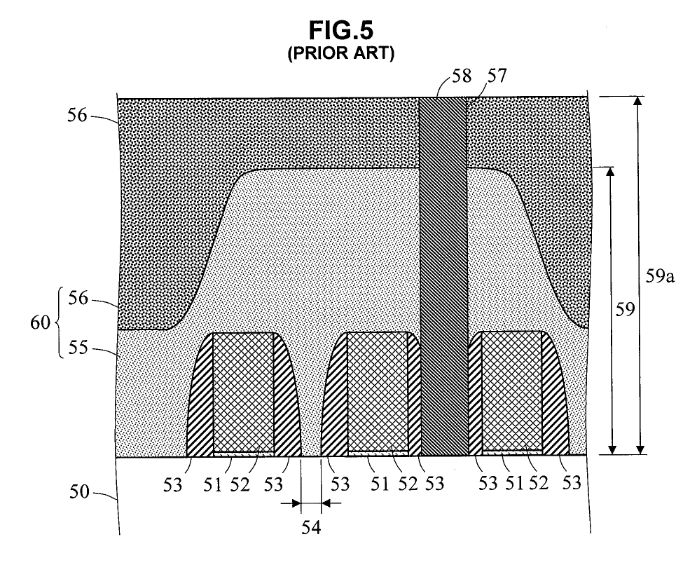

FIG. 2 is a chart showing the film thickness of the hygroscopic insulating film and the ratio of film thickness of the hygroscopic insulating film occupying in the total film thickness of the interlayer insulating film of this structure and the prior structure in case the height of the gate electrodes is 100 nm. Here, the film thickness of the low-hygroscopic insulating film covering the hygroscopic insulating film on the gate electrodes is made to the same (50 nm). In FIG. 2, the left vertical axis corresponds to the film thickness of the hygroscopic insulating film, and the right vertical axis corresponds to the ratio of film thickness of the hygroscopic insulating film occupying in the total film thickness of the interlayer insulating film. In the prior structure, the hygroscopic insulating film 55 having film thickness of the same extent as the height of the gate electrodes 52 is formed on the gate electrodes 52, therefore the maximum film thickness of the hygroscopic insulating film 55 becomes 200 nm (see FIG. 5). By contrast, the maximum film thickness of the hygroscopic insulating film 15 is about 105 nm according to the structure of this embodiment. Namely, the maximum film thickness 19 of the hygroscopic insulating film 15 can be nearly halved as compared to the prior structure. As a result, the ratio of film thickness of the hygroscopic insulating film occupying in the total film thickness of the interlayer insulating film in the gate electrode spacing was 80% in the prior structure while it becomes 105/155×100=68% in the structure of this embodiment. Namely, the ratio of hygroscopic insulating film 15 occupying in the entire interlayer insulating film 20 in the gate electrode spacing 14 can be made to less than 70% according to the structure of this embodiment.

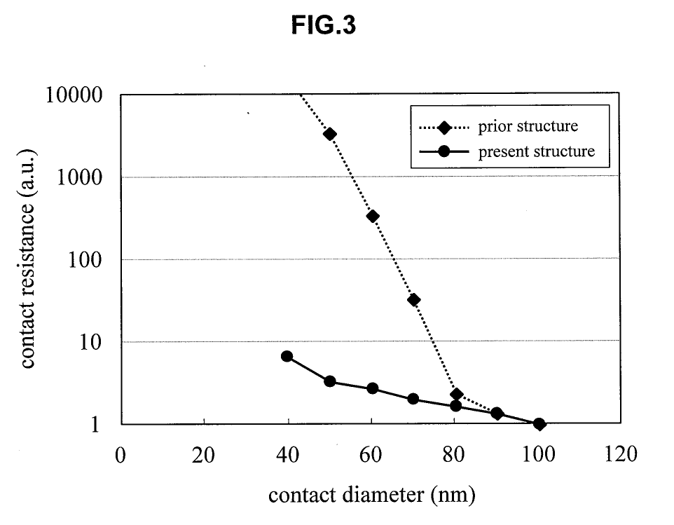

FIG. 3 is a graph showing a relationship between the contact diameter and the contact resistance for either of the prior structure and the structure of this embodiment. In FIG. 3, the horizontal axis corresponds to the contact diameter and the vertical axis corresponds to the contact resistance. As shown by a dotted line in FIG. 3, when the contact diameter becomes 80 nm or less, a rise of contact resistance becomes striking in the prior structure (the film thickness of the hygroscopic insulating film 55 is 200 nm, and the total film thickness of the interlayer insulating film 60 is 250 nm in the gate electrode spacing 54). By contrast, as shown with a solid line in FIG. 3, the rise of contact resistance is suppressed even if the contact diameter becomes 80 nm or less in the structure of this embodiment (the film thickness of the hygroscopic insulating film 15 is 105 nm, and the total film thickness of the interlayer insulating film 20 is 155 nm in the gate electrode spacing 14). This is because the film thickness of the hygroscopic insulating film 15 is thinned, therefore the amount of H₂O liberated from the hygroscopic insulating film 15 exposed as the inner surface of the contact hole 17 into the contact hole 17 can be reduced in the process for forming the contact hole 17. Therefore, according to the structure of this embodiment, the oxidation of the semiconductor substrate 10, particularly the oxidation of the nickel silicide surface active to oxidation can be inhibited, as a result, the rise of contact resistance can be suppressed.

As described above, the structure of this embodiment enables making the film thickness of the hygroscopic insulating film 15 as a reason for increase of contact resistance to necessary minimum. Therefore, when very fine contacts are formed in the interlayer insulating film including the hygroscopic insulating film, the rise of contact resistance can be suppressed. As a result, the contact resistance can be stabilized, and the semiconductor device can be stably manufactured at a high production yield.

When a substance as a reason for process contamination does not exist on the surface of the gate electrodes 12, e.g., the nickel silicide layer is not formed, the film thickness can also be further thinned within a range where the surface of the gate electrodes 12 does not expose. Moreover, the total film thickness 19a of the interlayer insulating film 20 was taken as 155 nm in the above description, but it is enough if the total film thickness 19a is 500 nm or less in the semiconductor device using the contact diameter of 80 nm.

Ranges of film thickness of the hygroscopic insulating film capable of filling a narrow gate electrode spacing also including the side walls and suppressing the rise of contact resistance at the contact diameter of 80 nm or less can be collected as a range where the following (1) and (2) are satisfied.

(1) The ratio of film thickness of the hygroscopic insulating film occupying in the total film thickness of the interlayer insulating film is more than or equal 10% and less than 70%.

(2) The ratio of film thickness of the hygroscopic insulating film to the height of gate electrodes on the gate electrodes is more than 0% and less than 100%.

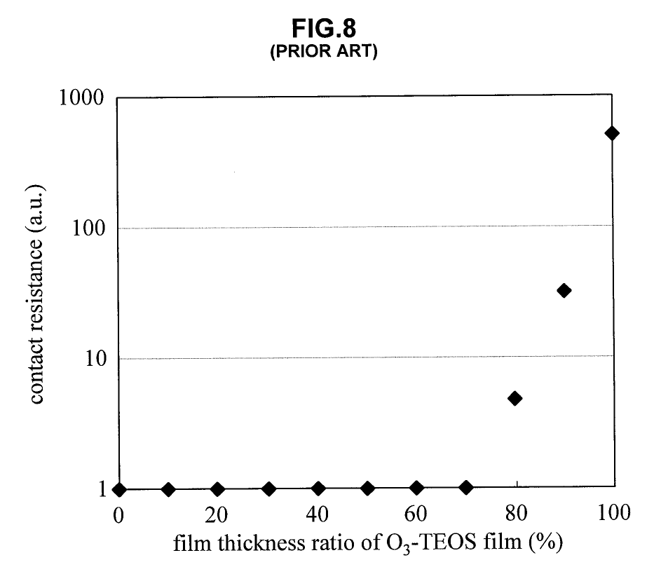

Here, the lower limit of the ratio of film thickness of the hygroscopic insulating film occupying in the total film thickness of the interlayer insulating film at the flat surface of the semiconductor substrate is taken as more than or equal 10%, because a narrow gate spacing can be fully filled even if the ratio is 10%. The upper limit of the ratio of film thickness of the hygroscopic insulating film occupying in the total film thickness of the interlayer insulating film at the flat surface of the semiconductor substrate is taken as less than 70% because the contact resistance rises from FIG. 8 if the ratio is more than 70%. If the ratios are converted, they become the upper limits of film thickness of (1) and (2).

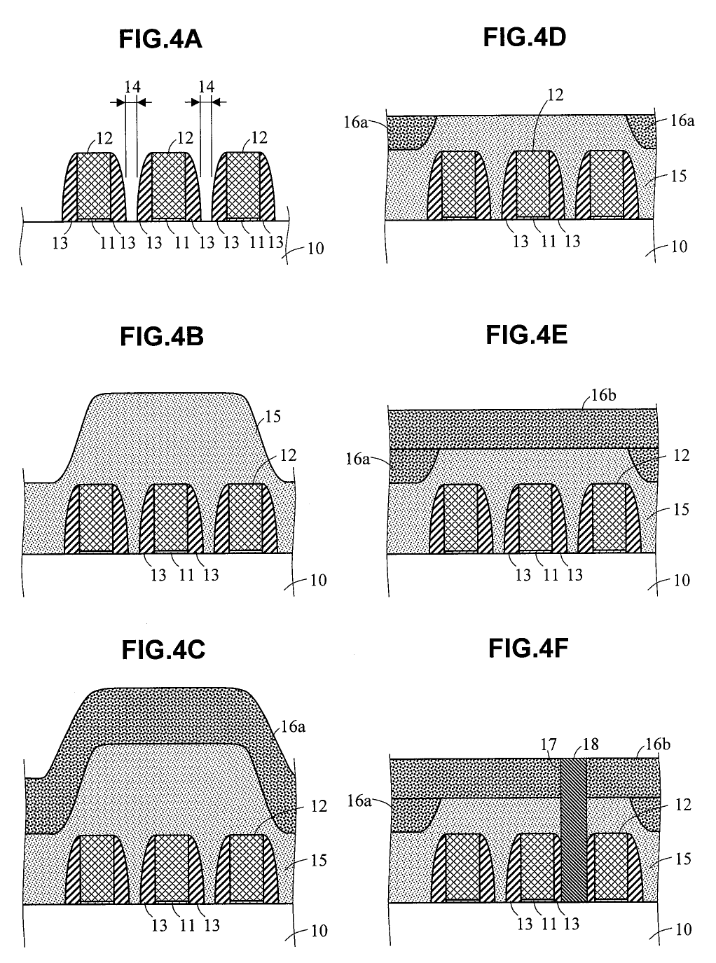

Successively, a method for manufacturing a semiconductor device capable of realizing the above structure is described. FIGS. 4A to 4F are sectional views showing a manufacturing process for the semiconductor device of this embodiment. As shown in FIG. 4A, in the semiconductor device manufacturing method of this embodiment, the multiple (three here) gate electrodes 12 are formed on the semiconductor substrate 10 consisting of a silicon single crystal substrate, and the side walls 13 are formed on the lateral surfaces of each gate electrode 12 at first. In this step, a gate insulating film 11 is formed on the semiconductor substrate 10. For example, a silicon oxide film formed by thermal oxidation process can be used as the gate insulating film 11. Element isolations such as STI (Shallow Trench Isolation), etc. are formed as necessary before the formation of the gate insulating film 11 on the semiconductor substrate 10. An N-type or P-type polycrystalline silicon film is formed on the semiconductor substrate 10 formed with the gate insulating film 11 by CVD method. The gate electrodes 12 are formed by applying well-known lithographic technique and etching technique to the polycrystalline silicon film. Here, the height of the gate electrodes 12 is 100 nm.

Next, an insulating film consisting of a silicon nitride film or a silicon oxide film or their laminated film is formed on the semiconductor substrate 10 formed with the gate electrodes 12 by CVD method. The side walls 13 consisting of the insulating film on the lateral surfaces of each gate electrode 12 are formed by applying anisotropic etching to the insulating film. As described above, the gate electrode spacing 14 becomes about several tens nm. Although an illustration is omitted, high concentration impurity regions of about 5E19/cm² to 5E20/cm² in impurity concentration are formed in the surface portion of the semiconductor substrate 10 by introducing impurities into the semiconductor substrate 10 with the gate electrodes 12 and the side walls 13 as a mask. The impurity regions function as a source region and a drain region of a transistor with the gate electrode 12 as constituents. An N-type or P-type impurity can be properly selected as an impurity introduced into the semiconductor substrate 10 in accordance with the conduction type of the semiconductor substrate 10. Such impurity regions are also formed in the gate electrode spacing 14.

In this embodiment, a nickel silicide layer is formed on the upside of each gate electrode 12 and the surface of the source region and drain region by a well-known salicide process. The nickel silicide layer is not necessarily formed, and the polycrystalline silicon constructing the gate electrodes 12 and the impurity regions (single crystal silicon) constructing the source region and drain region may also be a structure exposed to the surface.

Subsequently, as shown in FIG. 4B, the hygroscopic insulating film 15 covering the gate electrodes 12 and the side walls 13 is formed on the semiconductor substrate 10. In this embodiment, an O₃-TEOS film is formed as the hygroscopic insulating film 15. Thereby, as described above, the gate electrode spacing 14 can be completely filled without generating defects such as voids, etc. even if the gate electrode spacing 14 is as narrow as several tens nm. The O₃-TEOS film can be deposited by a sub-atmospheric thermal CVD (about 20 to 700 Torr) with O₃ and TEOS as starting materials. The substrate temperature in film-forming is about 300° C. to 450° C. Here, the film thickness of the O₃-TEOS film is taken as a height same as the gate electrodes 12 at the flat surface of the semiconductor substrate 10.

Successively, as shown in FIG. 4C, a first low-hygroscopic insulating film 16a constructing a part of the low-hygroscopic insulating film 16 is formed on the hygroscopic insulating film 15. Here, a plasma TEOS film is deposited as the first low-hygroscopic insulating film 16a. For example, the plasma TEOS film can be deposited by CVD method with O₂ gas and TEOS as starting materials. The substrate temperature in film-forming is about 300° C. to 450° C. In this embodiment, the film thickness of the plasma TEOS film at the flat surface of the semiconductor substrate 10 is made to 400 nm.

Subsequently, as shown in FIG. 4D, the surface of the laminated film comprising the hygroscopic insulating film 15 and the first low-hygroscopic insulating film 16a is planarized. In this embodiment, the planarizing is carried out by chemical mechanical polishing (CMP). The first low-hygroscopic insulating film 16a above the gate electrodes 12 is removed in the process of the planarizing, and the hygroscopic insulating film 15 exposes to the surface. Then, the planarizing is continued until a state that the film thickness of the hygroscopic insulating film 15 above the gate electrodes 12 finally remains to be about 5 nm. The planarizing can also be carried out by etch back using dry etching in place of CMP method.

After the completion of the planarizing, as shown in FIG. 4E, a second low-hygroscopic insulating film 16b constructing a part of the low-hygroscopic insulating film 16 is deposited on the semiconductor substrate 10. In this embodiment, a plasma TEOS film is formed under the same conditions as the step shown in FIG. 4C. Here, the film thickness of the plasma TEOS film is about 50 nm. This is because the hygroscopic insulating film 15 can prevent the remoistening if it is deposited to 50 nm or more.

After the completion of the formation of the second low-hygroscopic insulating film 16b, as shown in FIG. 4F, contacts are formed. In FIG. 4F, only one contact connecting electrically to the semiconductor substrate 10 between the right gate electrode 12 and the central gate electrode 12 in three gate electrodes is illustrated. The contact is constructed by the contact hole 17 passing through the hygroscopic insulating film 15 and the second low-hygroscopic insulating film 16b and the conductive contact plug 18 filling the contact hole 17. For example, the contact hole 17 is formed by etching away the second low-hygroscopic insulating film 16b and the hygroscopic insulating film 15 using dry etching via a mask pattern (e.g., resist pattern) having an opening at a position for forming the contact hole 17 on the second low-hygroscopic insulating film 16b. The dry etching can be carried out, for example, by a parallel-plate plasma dry etching apparatus. In this case, the dry etching can be performed, for example, under conditions of introducing CF₄ gas at a flow rate of 10 sccm, C₄F₆ gas at a flow rate of 20 sccm and O₂ gas at a flow rate of 20 sccm into an etching chamber and applying a high-frequency of 1,000 W to an upper electrode. The temperature of a lower electrode arranged with the semiconductor substrate 10 is about 0 to 20° C. (the temperature of the semiconductor device 10 is estimated to become about 100° C.). In this embodiment, the diameter of the contact hole 17 becomes 80 nm or less. In a region where the first low-hygroscopic insulating film 16a has not been removed, e.g., above the gate electrodes 12, in the above planarizing step, a contact hole for passing through the second low-hygroscopic insulating film 16b, the first low-hygroscopic insulating film 16a and the hygroscopic insulating film 15 is formed by the dry etching.

After the above mask pattern is removed by ashing, etc., a contact plug 18 is formed in the contact hole 17. In this embodiment, the contact plug 18 is formed by depositing titanium (Ti), titanium nitride (TiN) and tungsten (W) in order. Here, The Ti film of 10 nm in thickness is deposited, e.g., at a treating temperature of about 200 to 250° C. by PVD method. The TiN film of 5 nm in thickness is deposited, e.g., at a treating temperature of about 200 to 300° C. by CVD method. The W film of 200 nm in thickness is deposited, e.g., at a treating temperature of about 200 to 400° C. by CVD method. Unnecessary metal film on the second low-hygroscopic insulating film 16b is removed by CMP method. After the completion of the contact formation, wires for an upper layer and interlayer insulating films for an upper layer are formed on the upside of the second low-hygroscopic insulating film 16b to complete the semiconductor device.

In the semiconductor device formed by the above steps, the film thickness of the hygroscopic insulating film 15 filling the gate electrode spacing on the gate electrodes 12 becomes thinner than the film thickness on the flat surface of the semiconductor substrate 10. Accordingly, the ratio of film thickness of the hygroscopic insulating film 15 occupying in the total film thickness of the interlayer insulating film 20 can be decreased in the interlayer insulating film 20 deposited on the semiconductor substrate 10 at the gate electrode spacing 14. Therefore, the amount of H₂O liberated from the hygroscopic insulating film 15 exposed as the inner surface of the contact hole 17 into the contact hole 17 in the process of forming the contact hole 17 can be reduced. Accordingly, the oxidation of the semiconductor substrate 10 exposed into the contact hole 17, particularly the oxidation of the surface of the nickel silicide layer active to oxidation can be inhibited in the process of forming the contact, as a result, the rise of contact resistance can be suppressed.

As described above, the present invention enables making the film thickness of the hygroscopic insulating film to necessary minimum and reducing the amount of moisture released from the hygroscopic insulating film in the process of forming the contact. This enables inhibiting the oxidation of bottom of contact hole and suppressing the increase of contact resistance even if very fine contact hole is formed in narrow gate electrode spacing.

The present invention is not limited to the above-mentioned embodiment, and various modifications and applications are possible within a range where there is no deviation from the technical concept of the present invention. In the above description, the examples of forming contact in a narrow gate electrode spacing formed on the surface of the semiconductor substrate, but the present invention can give the same effects even the contacts are formed between multiple convexes formed on a semiconductor substrate. Moreover, the convexes are not limited to convexes formed just above the semiconductor substrate and may also be convexes formed on an interlayer insulating film. The materials of gate electrodes, side walls, hygroscopic insulating film and low-hygroscopic insulating films are not limited to the above materials and can be properly changed. The refractory metal silicides provided on the surface of the semiconductor substrate and the surface of gate electrodes are not limited to nickel silicide and may also be other refractory metal silicides. Furthermore, the process described in the above embodiment is possibly replaced by a well-known equivalent process.

The present invention is capable of suppressing the liberation of moisture from the hygroscopic insulating film, therefore it can also similarly improve the reliability of the upper wires (mainly copper wires).

The present invention has an effect capable of suppressing the rise of contact resistance even if very fine contacts are formed and is useful as a semiconductor device and a method of manufacture thereof.

What is claimed is:

1. A semiconductor device having multiple convexes formed on a semiconductor substrate, an interlayer insulating film covering the multiple convexes, a through-hole passing through the interlayer insulating film between the adjacent convexes and conductor plug filling the through-hole, the interlayer insulating film comprising:
a hygroscopic insulating film filling between the convexes adjacent to each other and having a thinner film thickness on the convexes than a film thickness on a flat surface of the semiconductor substrate; and
a low-hygroscopic insulating film formed on the hygroscopic insulating film.

2. A semiconductor device according to claim 1, wherein the multiple convexes are gate electrodes formed on the semiconductor substrate.

3. A semiconductor device according to claim 1, wherein the hygroscopic insulating film is an O₃-TEOS film.

4. A semiconductor device according to claim 2, wherein the hygroscopic insulating film is an O₃-TEOS film.

5. A semiconductor device according to claim 1, wherein a refractory metal silicide layer is formed on the surface of the semiconductor substrate between the convexes adjacent to each other.

6. A semiconductor device according to claim 2, wherein a refractory metal silicide layer is formed on the surface of the semiconductor substrate between the convexes adjacent to each other.

7. A semiconductor device according to claim 1, wherein the film thickness of the hygroscopic insulating film on the convexes is 5 nm or more.

8. A semiconductor device according to claim 2, wherein the film thickness of the hygroscopic insulating film on the convexes is 5 nm or more.

9. A semiconductor device according to claim 1, wherein the low-hygroscopic insulating film is a plasma TEOS film.

10. A semiconductor device according to claim 2, wherein the low-hygroscopic insulating film is a plasma TEOS film.

11. A semiconductor device according to claim 1, wherein a diameter of the through-hole is 80 nm or less.

12. A semiconductor device according to claim 2, wherein a diameter of the through-hole is 80 nm or less.

13. A method for manufacturing a semiconductor device, comprising the steps of:
forming gate electrodes on a semiconductor substrate;
forming a hygroscopic insulating film covering the gate electrodes;
forming a first low-hygroscopic insulating film on the hygroscopic insulating film;
exposing the hygroscopic insulating film on the gate electrodes to an upper surface and reducing the film thickness of the exposed hygroscopic insulating film by planarizing a surface of a laminated film consisting of the hygroscopic insulating film and the first low-hygroscopic insulating film;
forming a second low-hygroscopic insulating film on the planarized laminated film;
forming a through-hole passing through the second low-hygroscopic insulating film and the hygroscopic insulating film with the reduced film thickness at the time of the planarizing; and
filling the through-hole with a conductor.

14. A method for manufacturing a semiconductor device according to claim 13, wherein the hygroscopic insulating film is an O₃-TEOS film.

15. A method for manufacturing a semiconductor device according to claim 13, wherein the first low-hygroscopic insulating film is a plasma TEOS film.

16. A method for manufacturing a semiconductor device according to claim 13, wherein the second low-hygroscopic insulating film is a plasma TEOS film.

17. A method for manufacturing a semiconductor device according to claim 13, wherein the hygroscopic insulating film and the first low-hygroscopic insulating film are simultaneously planarized in the planarizing.

18. A method for manufacturing a semiconductor device according to claim 13, wherein the planarizing is carried out by chemical mechanical polishing.

19. A method for manufacturing a semiconductor device according to claim 13, wherein the planarizing is carried out by etch back using dry etching.
